(19) United States
(12) Patent Application Publication
(10) Pub. No.: US 2011/0130027 A1
(43) Pub. Date: Jun. 2, 2011

(54) SERVER SYSTEM AND SERVER SUITABLE FOR USE IN THE SERVER SYSTEM AND SUITABLE CONNECTION MODULE

(75) Inventor: Ewald Harms, Schlangen (DE)

(73) Assignee: Fujitsu Technology Solutions Intellectual Property GmbH, Munich (DE)

(21) Appl. No.: 12/995,505

(22) PCT Filed: May 22, 2009
(86) PCT No.: PCT/EP09/56250

§ 371 Date: Jan. 4, 2011

(30) Foreign Application Priority Data
Jun. 3, 2008 (DE) 10 2008 026 538.1

(51) Int. Cl. H01R 13/64; G06F 1/26; H05K 5/00

(52) U.S. Cl. 439/374; 713/300; 361/679.02

(57) ABSTRACT

A server system includes a server frame with a first side and a second side for insertion of at least one server from the first side of the server frame, at least one connection module for the connection of the at least one server inserted into the server frame from the second side of the server frame opposite the first side, wherein the at least one connection module is arranged transversely with respect to the at least one server, at least one plug connector provided for the server, and at least one additional plug connector provided for the connection module in such a manner that a direct connection between the connection module and the server is produced by the plug connector of the server and the plug connector of the connection module.

### RELATED APPLICATIONS

This is a §371 of International Application No. PCT/EP2009/056250, with an international filing date of May 22, 2009 (WO 2009/147019 A1, published Dec. 10, 2009), which is based on German Patent Application No. 10 2008 026 538.1, filed Jun. 3, 2008, the subject matter of which is incorporated by reference.

### TECHNICAL FIELD

This disclosure relates to a server system with a server frame. The disclosure further relates to a server and a connection module for use in the server system.

### BACKGROUND

A server system generally comprises a plurality of servers that are placed, generally in the form of inserts, into a shared server frame, or also into several server frames (racks) and are connected to a common network. The server system also has powerful CPUs (central processing units), and large RAM memories, as well as a large hard disk capacity to meet modern requirements for speed and computational capacity. For reasons of space and efficiency, the servers themselves generally have no additional infrastructure (servers designed in this manner are generally referred to as blade servers). The infrastructure that can comprise, among other things, one or more power supplies (power adapters), optical disks, fans or network switches and that is required—and jointly used—by the servers of the server system is generally connected to the servers in the form of connection modules via one or two so-called “midplanes.”

The midplane is generally situated in the center of the server system. It has two sides, each with a plurality of connectors. The servers are plugged in from one side of the midplanes and the various connection modules from the other side and are, therefore, electrically connected to the midplane. An electrical connection between the servers and the connection modules is produced by the midplane, and both a transfer of data from and to the servers and also a supply of power to the servers are assured.

The midplane, however, is a very complex and also very expensive component of the server system. Furthermore, signal integrity is negatively influenced by the two respectively required connections (between the connection module and the midplane and between the server and the midplane). Moreover, the connection modules must be unplugged from the midplane and removed for maintenance purposes to reach the midplane and perform the repairs. Troubleshooting also proves difficult in the case of a connection of the servers and the connection modules to a midplane since a direct localization of the error that has occurred is often very complicated or completely impossible due to the additional connections through the midplane. A midplane also represents a not insignificant hindrance to the cooling air stream, which is generally guided through the server system from the front to the back.

It could therefore be helpful to provide a server system that has a simple structure and in which a connection between the servers and the connection modules is produced by which signal integrity is not impaired, which presents the smallest possible flow resistance to a cooling air stream, and with which maintenance and any necessary troubleshooting are considerably facilitated.

### SUMMARY

I provide a server system including a server frame with a first side and a second side for insertion of at least one server from the first side of the server frame, at least one connection module for the connection of the at least one server inserted into the server frame from the second side of the server frame opposite the first side, wherein the at least one connection module is arranged transversely with respect to the at least one server, at least one plug connector provided for the server, and at least one additional plug connector provided for the connection module in such a manner that a direct connection between the connection module and the server is produced by the plug connector of the server and the plug connector of the connection module.

I also provide a server for use in the server system, wherein the server includes at least one plug connector that directly connects the server to a connection module inserted into the server system.

I further provide a connection module for use in the server system, wherein the connection module includes at least one plug connector for the direct connection of the connection module to a server inserted into the server system.

### BRIEF DESCRIPTION OF THE DRAWINGS

FIG. 1 is a schematic representation of the server system in accordance with the application.

FIG. 2 is a schematic representation of a side view of the server system represented in FIG. 1.

FIG. 3 is a schematic representation of the server system from FIG. 2 in an additional embodiment.

### LIST OF REFERENCE NUMBERS

1 Server system
2 Server frame
3 First side
4 Second side
5 Server
6 Connection module
7 Plug connector
8 Guide element
9 Plug connector
10 Guide element

### DETAILED DESCRIPTION

I provide a server system that has a server frame with a first side and a second side for the insertion of at least one server from the first side of the server frame, as well as at least one connection module for the connection of the at least one server inserted into the server frame from the second side of the server frame opposite the first side, wherein the at least one connection module is arranged transversely with respect to the at least one server. The server system is characterized in that at least one plug connector for the server and at least one additional plug connector for the connection module are provided for the server in such a manner that a direct connection between the connection module and the server can be produced by the plug connector of the server and the plug connector of the connection module.

A direct connection between the server and the connection module is enabled by the suitable plug connectors of the server and the plug connectors of the connection module. A detour via an expensive and complex midplane to produce the electrical connection, and thus twice the number of plug connections for the electrical signal (namely, on one hand, the plug connections from the server to the midplane and, on the other hand, the series-connected plug connections from the midplane to the connection module) is therefore superfluous and signal integrity is preserved when the server and the connection module are connected.

Preferably, a guide element is provided on each connection module to guide the plug connector of the server to the additional plug connector of the connection module. An incorrect electrical connection between the plug connector of the server and the plug connector of the connection module can be avoided by such guidance.

In a likewise preferred configuration, a respective additional guide element cooperating with the guide element of the connection module is provided on the server.

Preferably, the at least one guide element is provided on the plug connector of the connection module and the at least one additional guide element interacting with it is provided on the plug connector of the server.

Preferably, the at least one connection module is a power supply unit for the supply of power to the at least one server.

Likewise preferably, the at least one connection module is an I/O module.

I also provide a server for use in the server system having the at least one plug connector for the direct connection to a connection module inserted into the server system.

By means of the suitable configuration of the at least one plug connector of the server, a simple, direct connection between the server and the connection module, for example, a power supply, an I/O module or a fan is made possible. An expensive and complicated midplane for the connection of the server to an infrastructure can thus be omitted. The structure of the server system thereby becomes substantially more clear and troubleshooting in the case of a fault is considerably facilitated.

Preferably, the server is provided such that the plug connector is furnished in a multiple-instance design on the server, the multiple plug connectors being provided to create a respective direct connection between the server and several connection modules inserted into the server system.

Preferably, at least one guide element is provided on the server to guide the at least one plug connector of the server to an additional plug connector of the connection module.

Another preferred configuration provides that the plug connectors comprise network plug connections and/or additional I/O plugs.

In a likewise preferred configuration, the plug connector comprises power supply terminals.

The problem is further solved by a connection module for use in the server system that is characterized in that the connection module has at least one plug connector for the direct connection of the connection module to a server inserted into the server system.

An accurately fitting attachment of the plug connector of the connection module to the plug connector of the server, and thus the production of a direct electrical connection between server and connection module, is achieved by a suitable design of the at least one plug connector of the connection module as well as the at least one guide element and their interaction—without the need for additional connections or multiple plug connections via a midplane. Thereby, the signal integrity for the connection of the connection module to the server is preserved. Possible faults in the connections or on the connection modules themselves can be quickly localized and remedied.

In a preferred configuration of the connection module, at least one guide element is provided for the guidance of the at least one plug connector of the connection module to an additional plug connector on the server. Thereby, it is assured that the plug connector of the server and the plug connector of the connection module are matched to one another within predetermined tolerances, whereby an optimal signal transmission is guaranteed.

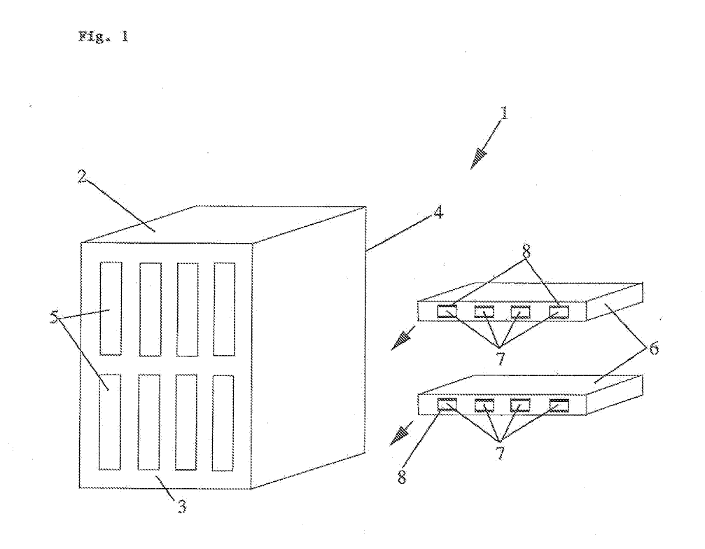

Turning now to the drawings, FIG. 1 shows a schematic representation of the server system 1. The server system 1 comprises a server frame 2 with a first side 3 and a second side 4, as well as several servers 5. The server system 1 further contains two connection modules 6, each with several plug connectors 7 as well as guide elements 8.

The server system 1 as shown can be, for example, a blade server system for the accommodation of blade servers in the server frame 2. The advantage of a blade server system is its compact construction, and consequently a high power density of the server system 1. The server frame 2 can of course also be provided for the accommodation of a different server 5.

The servers 5 are inserted in this example from the first side 3 of the server frame 2—referred to below as the front side 3 of the server frame 2—in the form of inserts into the server system 1. For reasons of clarity, FIG. 1 shows only eight servers 5 in two rows one above the other, but the server system 1 could also have a larger number of servers 5. The second side 4 of the server frame 2 opposite the front side 3 will be referred to below as the rear side 4 of the server frame 2.

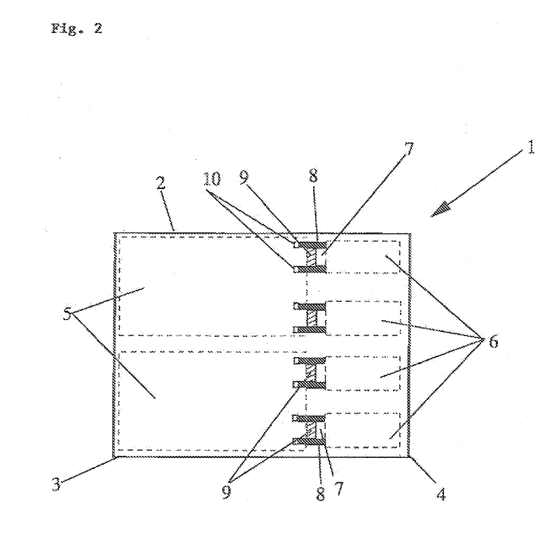

On a rear side, the servers 5 have plug connectors not shown here (refer to FIG. 2 for a schematic representation of the plug connectors as well as the connection of servers 5 and connection modules 6), wherein an infrastructure in the form of connection modules 6 is connected to the servers 5 from the rear side 4 of the server frame 2 by means of these plug connectors. The plug connectors of the servers 5 could be configured as sockets and/or as plugs.

The connection modules 6, each of which is inserted transversely with respect to the servers 5 into the server frame 2, have the additional plug connectors 7, each of which can be inserted into a plug connector of the server 5 depending upon the presence of plug connectors on the servers 5, or can remain empty. The plug connectors 7 of the connection modules 6 can likewise be constructed as sockets and/or as plugs.

The servers 5 and the connection module 6 are mechanically guided in the server frame 2—for example, by a rail system—wherein servers 5 and connection modules 6 are fit into the server frame 2 in such a manner that the plug connectors of the servers 5 and the plug connectors 7 of the connection modules 6 can be fit one in the other within predetermined tolerances.

In this structure, two guide elements 8 are mounted on the plug connectors 7 of the connection modules 6. The guide elements 8 can be constructed, for example, in the form of metal rails or plastic rails and assure a precise guidance of the plug connectors 7 of the connection modules 6 with respect to the respective matching plug connectors on the rear side of the servers 5. For this purpose, for example, it is possible to provide additional guide elements, not shown in FIG. 1, on the servers 5 interacting with the guide elements 8.

Of course, the guide elements 8 of the connection modules may not necessarily be mounted on the plug connectors 7, but instead the guide elements 8 could be mounted at another position on a side of the connection modules 6 facing the servers 5. Due to the simple configuration of the guide elements 8, series production and mounting of the guide elements 8 is possible without large additional effort or increased costs.

The connection modules 6 can comprise, for example, one or more power supplies (power adapters) that can also be used jointly by the servers 5 as power supplies. The connection modules 6 can likewise be I/O modules for the connection of the servers 5 to optical drives, for example, or for the connection to a network.

FIG. 2 shows a schematic representation of a side view of the server system 1 shown in FIG. 1. The same reference numerals as those for the description of FIG. 1 apply.

The server system 1 comprising the server frame 2 with the front side 3 and the rear side 4, as well as the servers 5, are shown. The server system 1 likewise comprises the connection modules 6, each containing at least one plug connector 7 on which the guide elements 8 are mounted. The servers 5 each have plug connectors 9 and guide elements 10.

The server system 1 can again be a blade server system 1. The servers 5 that are inserted into the server system 1 and have been pushed in from the front side 3 of the server frame 2 are shown using dashed lines, since they are covered by an outer side (side surface) of the server frame 2. In addition, due to the side view of the server system 1, only two servers 5 are visible. The connection modules 6 are likewise shown using dashed lines, to clarify that they are covered in this view by the outer side (side surface) of the server frame 2.

It can be seen in FIG. 2 that two connection modules 6 are provided for each server 5, wherein the connection modules 6 are each inserted into the server frame 2 transversely with respect to the servers 5. The connection modules 6 can again be power supply units or I/O modules.

The plug connectors 7 of the connection modules 6 are inserted into the plug connectors 9 mounted on the rear side of the servers 5 which—exactly like the plug connectors 7 of the connection modules 6—can be configured as a plug and/or as a socket, depending on the respective configuration of the plug connectors 7 of the connection modules 6. Thus the connection modules 6 are electrically connected directly to the servers 5—a complex midplane for the production of the electrical connection between server 5 and connection module 6 is superfluous. For each server 5 of the server system 1, at least one plug connector 7 of a connection module 6 should be provided.

The servers 5 or the connection modules 6 can also have multiple plug connectors 9 or 7, respectively, (or plug groups of plug connectors 9, 7), by means of which the direct connection is produced. The multiple plug connectors 7 of the connection modules 6 can be constructed across an entire width of the connection modules 6. The plug connectors 9, 7 can be arranged in groups of plug connectors 9, 7, each having a defined function (I/O plug connectors, power supply terminals and the like).

The connection modules 6 each have two guide elements 8, mounted in this example on the plug connectors 7. The guide elements 8 each fit the plug connectors 7 mechanically into the plug connectors 9 of the servers 5 within predetermined tolerances. For that purpose, additional guide elements 10 cooperating with the guide elements 8 are provided on the servers 5. The guide elements 10 can be configured, for example, as a protrusion 5 into the servers 5 or into the plug connectors 9 of the servers 5, wherein a shape or size of the protrusion or the guide elements 10 in general are matched to a shape and size of the guide elements 8.

Errors in the signal transmission due to incorrectly plugged-in connections between the servers 5 and the connection modules 6 are avoided by the optimal matching of the guide elements 8, 10 and the plug connectors 7, 9, as well as by their cooperation. In addition, damage to the plug connectors 7, 9 is prevented by the guide elements 8, 10.

The guide elements 8 can be configured as short, metallic rail pieces that are mounted (for example, glued or bolted) on a front side of the connection module 6 around the plug connector 7. As already mentioned in the description of FIG. 1, a plastic rail is also conceivable as a guide element 8. The two guide elements 8 define the (direct) connection between the servers 5 and the connection modules 6 in two dimensions. Of course it is also possible to provide not only two, but also more guide elements 8 per connection module 6 as well as corresponding guide elements 10 on the servers 5. It is likewise conceivable to place the guide elements 8 in the configuration described above directly on the server 5, whereby the correspondingly configured guide elements 10 on the servers 5 can be omitted.

It is further conceivable that a constant position relative to the server 5 is always provided for one or more defined plug connectors 7 of the connection modules 6. Thus, for example, the lowest or the highest connection module 6 could always be a power supply unit for the supply of power to the servers 5 (in the lower or upper row, respectively).

The number of plug connectors 7 present on a connection module 6, or the number of plug connectors 9 present on a server 5, need not necessarily be consistent with a number of plug connectors 7, 9 involved in the direct electrical connection of servers 5 and connection modules 6, but instead a markedly larger number of a plug connectors 7, 9 can be provided on the connection modules 6 or the servers 5, respectively. The number of plug connectors 7, 9 involved in the direct electrical connection of server 5 and connection module 6 corresponds to the number of plug connectors 7 and 9 in corresponding functions and those provided for an operation in the server system 1.

Due to the cooperation of the plug connectors 9 of the servers 5, the plug connectors 7 of the connection modules 6 and the guide elements 8, 10, an accurately fitting direct connection between servers 5 and connection modules 6 is achieved, without an intermediate, complex and expensive midplane being necessary for the connection of the servers 5 to the connection modules 6. Both effort in the production and also costs can be saved in this way. In addition, the total number of (plug) connections that must be present for the electrical connection can be reduced by half, since a series-connected plug connection from the servers 5 to a midplane and from the midplane to the connection modules 6 is no longer necessary. Thereby the fault-susceptibility of the server system 1 can be significantly reduced.

If a fault appears in the server system 1, for example, if one of the servers 5 is not supplied with power, then the source of the fault can be quickly localized due to the smaller number of connections, and the fault can be remedied, even without having to disconnect all of the connection modules 6, thus interrupting the operation of the entire server.

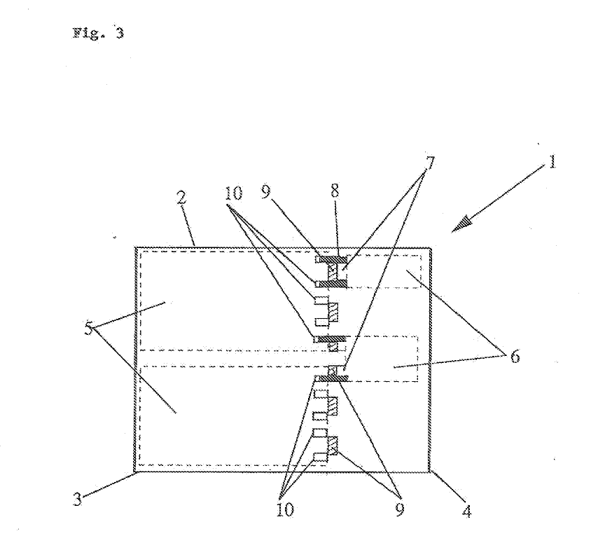

FIG. 3 shows a schematic representation of the server system 1 illustrated in FIG. 2 in an additional example. The same reference numerals apply as in the description of FIG. 2.

Once again, the server system 1 that consists of the server frame 2 with the front side 3 and the rear side 4, as well as the servers 5, are shown. This server system 1 further comprises two connection modules 6 with plug connectors 7 on which the guide elements 8 are placed. The servers 5 each comprise the plug connectors 9 and the guide elements 10.

The configuration already mentioned in the description of FIG. 2, in which a constant position relative to the server 5 is always provided for one or more defined plug connectors 7 of the connection modules 6, is again taken up in this example and will be explained further.

In FIG. 3, the plug connectors 9 arranged at an upper end of the rear side of the server 5 are provided as terminals for the supply of power to the servers 5. Accordingly, the connection modules 6 that are connected to the upper plug connectors 9 of the servers 5 are configured as power supply units (and the plug connectors 7 of the connection modules 6 are consequently power supply terminals).

Furthermore, as shown here, an additional, lower plug connector 9 of the servers 5 can be provided as a terminal for the supply of power to the server 5. Thereby, usage of a number of power supply units corresponding to the number of servers 5 is possible. Due to the arrangement of the plug connectors 7, 9 and the constant position of the plug connectors 7 of the connection modules 6 (power supply units) relative to the servers 5, however, a redundant supply of power is enabled in this example, which further reduces the fault-susceptibility of the server system 1.

In addition to power supply units as connection modules 6, other connection modules 6 (such as I/O modules) can of course be provided, but are not shown here for reasons of clarity.

In this example, as well as those shown in FIGS. 1 and 2, the direct connection between the servers 5 and the connection module 6 can be used for all necessary electrical connections. In this case, both power supply units for the supply of power to the servers 5 and I/O modules for data exchange are provided as connection modules 6. In such a case, a midplane is completely unnecessary.

It is alternatively also possible, however, to provide the direct connection of servers 5 and connection modules 6 for only a part of the electrical connection of the servers 5, for example, the data connections. The remaining electrical connections such as those for the supply of power to the servers 5 can be conducted by means of a midplane that is then, unlike the known midplanes, constructed over only a part of the overall height of the server in the vertical direction. Such a midplane influences a cooling air stream less than the known midplanes, which are typically constructed over the entire surface area behind the servers 5. Another advantage is that the better signal quality of the direct connection between servers 5 and connection modules 6 can be used for the data lines, whereas conventional power supply modules suitable for the connection via a midplane can be used for the supply of power, which is less demanding with respect to signal quality.

1-15. (canceled)

16. A server system comprising:
a server frame with a first side and a second side for insertion of at least one server from the first side of the server frame;
at least one connection module for the connection of the at least one server inserted into the server frame from the second side of the server frame opposite the first side, wherein the at least one connection module is arranged transversely with respect to the at least one server;
at least one plug connector provided for the server; and
at least one additional plug connector provided for the connection module in such a manner that a direct connection between the connection module and the server is produced by the plug connector of the server and the plug connector of the connection module.

17. The server system according to claim 16, further comprising at least one guide element provided on each connection module that guides the plug connector of the server to the additional plug connector of the connection module.

18. The server system according to claim 16, further comprising at least one additional guide element interacting with the guide element provided on the server.

19. The server system according to claim 17, wherein the at least one guide element is provided on the plug connector of the connection module and the at least one additional guide element interacting with it is provided on the plug connector of the server.

20. The server system according to claim 16, wherein the at least one connection module is a power supply unit that supplies power to the at least one server and/or is an I/O module.

21. The server system according to claim 16, wherein the at least one server is a blade server.

22. A server for use in a server system according to claim 16, wherein the server comprises at least one plug connector that directly connects the server to a connection module inserted into the server system.

23. The server according to claim 22, wherein the plug connector is provided in a multiple-instance design on the server, the multiple plug connectors being provided to create a respective direct connection between the server and several connection modules inserted into the server system.

24. The server system according to claim 22, Wherein at least one guide element is provided on the server to guide the at least one plug connector of the server to an additional plug connector of the connection module.

25. The server according to claim 22, wherein the plug connectors comprise network plug connectors and/or additional I/O plugs and/or power supply terminals.

26. The server according to claim 22, wherein the server is a blade server.

27. A connection module for use in a server system according to claim 16, wherein the connection module comprises at least one plug connector for the direct connection of the connection module to a server inserted into the server system.

28. The connection module according to claim 27, wherein the at least one guide element is provided on the connection module to guide the at least one plug connector of the connection module to an additional plug connector of the server.

29. The connection module according to claim 27, wherein at least one plug connector of the connection module is provided for each server of the server system.

30. The connection module according to claim 27, wherein the connection module is an I/O module or a power supply unit.

31. The server system according to claim 17, further comprising at least one additional guide element interacting with the guide element provided on the server.

32. The server system according to claim 18, wherein the at least one guide element is provided on the plug connector of the connection module and the at least one additional guide element interacting with it is provided on the plug connector of the server.

33. The server system according to claim 23, wherein at least one guide element is provided on the server to guide the at least one plug connector of the server to an additional plug connector of the connection module.

34. The connection module according to claim 28, wherein at least one plug connector of the connection module is provided for each server of the server system.
